(19) United States
(12) Patent Application Publication
(10) Pub. No.: US 2011/0241036 A1
(43) Pub. Date: Oct. 6, 2011

(54) LIGHT-EMITTING APPARATUS

(75) Inventors: Hideki Yoshinaga, Mobara-shi (JP); Hideo Mori, Mobara-shi (JP)

(73) Assignee: CANON KABUSHIKI KAISHA, Tokyo (JP)

(21) Appl. No.: 12/528,904

(22) PCT Filed: Jun. 17, 2009
(86) PCT No.: PCT/JP2009/061435

§ 371 Date: Aug. 27, 2009

(30) Foreign Application Priority Data
Jun. 30, 2008 (JP) 2008-171749

(51) Int. Cl. H01L 27/15

(52) U.S. Cl. 257/89; 257/E27.121

(57) ABSTRACT

Provided is a light-emitting apparatus including a plurality of light-emitting devices arranged on a substrate, the plurality of light-emitting devices each including a pair of electrodes and an organic emission layer which is interposed between the pair of electrodes with one of the pair of electrodes serving as an anode and another one of the pair of electrodes serving as a cathode, wherein one of the pair of electrodes is an electrode common to the plurality of light-emitting devices, and wherein, of the plurality of light-emitting devices, ones that have the common electrode as their anodes and ones that have the common electrode as their cathodes are arranged alternately.

### TECHNICAL FIELD

The present invention relates to a light-emitting apparatus including light-emitting devices, specifically, organic electroluminescent devices.

### BACKGROUND ART

Electroluminescence (hereinafter simply referred to as EL) of an organic material is used in an organic EL device in which an organic layer is interposed between a first electrode and a second electrode. The organic EL devices are attracting attention as a light-emitting device capable of emitting light of a high luminance while driven at low voltage. A light-emitting apparatus with organic EL devices arranged in a matrix pattern on a substrate is used as a display apparatus.

A self-emission type display apparatus that uses an organic EL device as described above (namely, organic EL display) includes a thin film transistor (hereinafter referred to as TFT) in each pixel on a substrate. The TFT is covered with an interlayer insulating film on which the organic EL device is formed. The organic EL device is connected to the TFT, and is formed of a first electrode, an organic layer, and a second electrode. The first electrode in one pixel is separated from and independent of the first electrodes in other pixels. The organic layer includes an organic emission layer. The second electrode is placed so as to cover the organic layer. The central part of the first electrode is exposed as a pixel opening, instead of being under an insulative device separation film which covers the periphery of the central part. Above the exposed first electrode, the organic layer including the organic emission layer is provided, and the second electrode is provided so as to cover the organic layer. The second electrode is usually formed in a manner that covers a plurality of pixels to be used as an electrode common to the plurality of pixels.

The thus structured active matrix display is known to employ, as a measure to secure a light emission region (aperture ratio) in one pixel region of the organic EL device, a so-called top emission structure in which light is extracted from the front side of the substrate.

When the top emission structure is employed, a film used as the second electrode is, in order to ensure the light transmissivity, a transparent oxide film that has a relatively high resistivity or a metal thin film that is thin enough to have semi-transmissive characteristics. This makes the resistance value of the second electrode high, and shading (phenomenon in which the luminance becomes nonuniform within a plane) occurs corresponding to the amount of voltage drop caused by the resistance of the second electrode.

As a solution to the shading, there is proposed a structure in which an auxiliary wiring line formed of a high conductivity metal material is provided in a region other than the light emission region in the pixel region, and connected to the second electrode, to thereby lower the resistance value of the second electrode.

Japanese Patent Application Laid-Open Nos. 2007-092109 and 2003-316291 each disclose a method in which an auxiliary electrode is formed, by evaporation, with the use of a shadow mask, on the second electrode which is a layer above insulative separation films formed between the light emission regions of the respective pixels when the organic EL device substrate is viewed from above and which is a non-light emission region.

The main purpose of the auxiliary wiring line is, as described above, to lower the resistance value of the second electrode without hindering light emission by organic EL devices. For that purpose, the auxiliary wiring line needs to have a narrow width so as to be disposed between pixels in a display region, and also needs to extend over the outside of the display region. However, there arises a problem that twisting or warping of a shadow mask used for the evaporation breaks a pattern of the auxiliary wiring line or makes the width of the auxiliary wiring line nonuniform.

Japanese Patent Application Laid-Open No. 2005-189676 discloses a method in which an auxiliary electrode is formed by photolithography on the same layer as the first electrode, and the second electrode is formed on a selectively formed organic layer. The auxiliary electrode and the second electrode are electrically connected to each other at a portion in which the organic layer is not present.

Forming the auxiliary wiring line by photolithography at the same time when an Al or other wiring line of the first electrode layer is formed is effective in avoiding the problem raised from the use of a shadow mask. However, widening the wiring width of the auxiliary wiring line that is formed on the same layer as the first electrode is difficult because of limited dimensions allocated to the auxiliary wiring line. When the display screen size is large, in particular, the lengthened auxiliary wiring line raises the resistance value, whereby the resistance value of the second electrode may not be lowered to a desired value.

The method also requires the production process of the auxiliary wiring line to include a step of exposing the auxiliary wiring line by, for example, evaporation that selectively deposits the organic layer, so that the auxiliary wiring line formed in the same layer as the first electrode and the second electrode may be electrically connected to each other after the organic layer is formed.

Lowering the resistance of the second electrode with the use of the auxiliary wiring line thus presents difficulties in terms of precision as well as production steps, and has not succeeded in completely preventing shading.

### DISCLOSURE OF THE INVENTION

An object of the present invention is to reduce shading resulting from a voltage drop due to a resistance of a second electrode with an inexpensive and simple structure.

The present invention provides a light-emitting apparatus including a plurality of light-emitting devices arranged on a substrate, the light-emitting devices each including a pair of electrodes and an organic emission layer which is interposed between the pair of electrodes with one of the pair of electrodes serving as an anode and the other of the pair of electrodes serving as a cathode,

wherein one of the pair of electrodes is an electrode common to the plurality of light-emitting devices, and

wherein, of the plurality of light-emitting devices, ones that have the common electrode as their anodes and ones that have the common electrode as their cathodes are arranged alternately.

According to the present invention, organic light-emitting diode devices each having a cathode terminal connected to a common electrode and organic light-emitting diode devices each having an anode terminal connected to the common electrode are arranged alternately to coexist. This causes a differential current to flow in the common electrode, thereby reducing the voltage drop.

The amount of current supplied to the common electrode is small, and thus a line width of a current supply wiring line disposed at the outer periphery of the display region may be made thinner, and the organic EL device panel may accordingly have a narrower frame width.

Unlike the conventional methods of preventing shading, the present invention does not need to lower the resistance value of the common electrode or of a line for supplying current to the common electrode.

Further features of the present invention will become apparent from the following description of exemplary embodiments with reference to the attached drawings.

### BRIEF DESCRIPTION OF THE DRAWINGS

FIG. 1 is a diagram illustrating colors that are displayed by subpixels of a light-emitting apparatus according to a first embodiment of the present invention, and directions of currents that flow in the subpixels;

FIG. 2 is a schematic cross-sectional view illustrating the light-emitting apparatus according to the first embodiment of the present invention;

FIG. 3 is a diagram illustrating an equivalent circuit of the light-emitting apparatus according to the first embodiment of the present invention;

FIG. 4 is a diagram illustrating colors that are displayed by subpixels of a light-emitting apparatus according to a second embodiment of the present invention, and directions of currents that flow in the subpixels;

FIGS. 5A and 5B are diagrams illustrating colors that are displayed in two subfields by a light-emitting apparatus according to a third embodiment of the present invention, and directions of currents that flow in the subfields;

FIG. 6 is a schematic cross-sectional view illustrating the light-emitting apparatus according to the third embodiment of the present invention;

FIG. 7 is a diagram illustrating an equivalent circuit of the light-emitting apparatus according to the third embodiment of the present invention; and

FIGS. 8A and 8B are diagrams illustrating colors that are displayed in two subfields by a light-emitting apparatus according to a fourth embodiment of the present invention, and directions of currents that flow in the subfields.

### BEST MODE FOR CARRYING OUT THE INVENTION

Embodiments of the present invention are described below. Components that are not specifically illustrated in the accompanying drawings or described herein are applications of well-known technologies in the technical field of the present invention. In addition, the embodiments described below are merely some of modes for carrying out the present invention, and the present invention is not limited thereto.

### First Embodiment

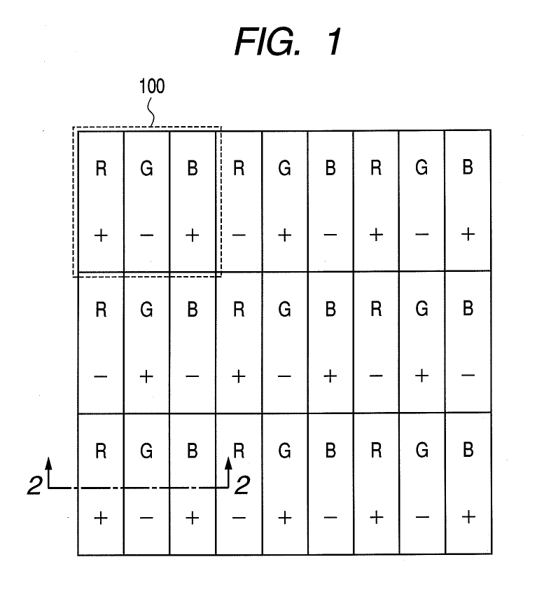

FIG. 1 illustrates an example in which a light-emitting apparatus according to a first embodiment of the present invention is used as a display. A pixel 100 is composed of three subpixels, R, G, and B, which include organic EL light-emitting devices of three different colors, red (R), green (G), and blue (B), respectively.

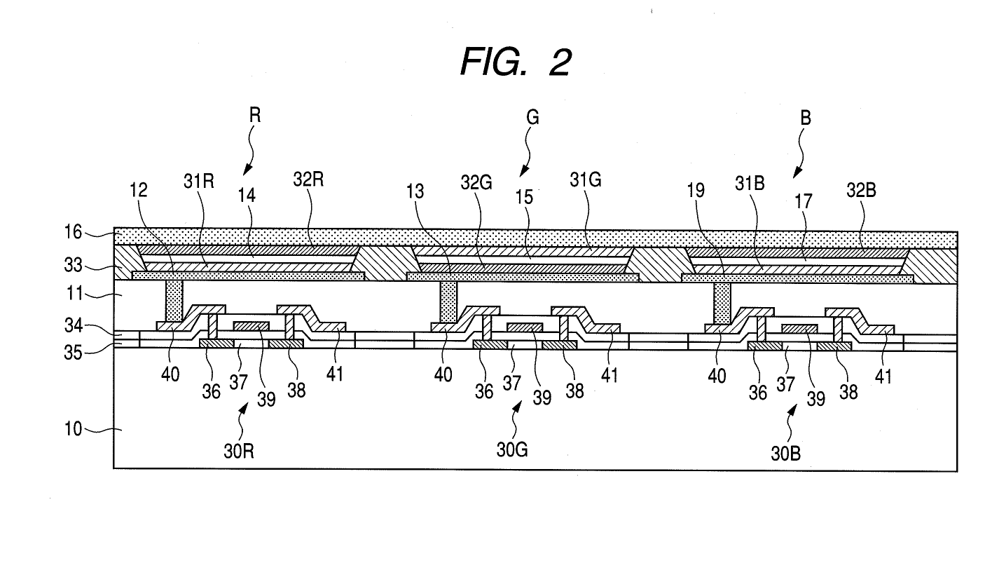

FIG. 2 is a cross-sectional view of a single pixel 100 taken along line 2-2 of FIG. 1.

The R subpixel is driven by a thin film transistor (TFT) 30R. The R subpixel includes, on a lower electrode 12 connected to a drain electrode 40 of the TFT 30R, a hole injection layer 31R, a light emission layer 14, and an electron injection layer 32R which are stacked in the mentioned order and covered with an upper electrode 16.

The G subpixel next to the R subpixel is driven by a thin film transistor (TFT) 30G. The G subpixel includes, on a lower electrode 13 connected to a drain electrode 40 of the TFT 30G, an electron injection layer 32G, a light emission layer 15, and a hole injection layer 31G which are stacked in the mentioned order and covered with the upper electrode 16. The order of the three layers forming the organic layer is reverse in the R subpixel and in the G subpixel.

The B sub-pixel is driven by a thin film transistor (TFT) 30B. The B subpixel is similar to the R subpixel in that its organic layer, namely, a hole injection layer 31B, a light emission layer 17, and an electron injection layer 32B are stacked in the mentioned order on a lower electrode 19.

The organic EL devices are structured such that a light emission layer is sandwiched between a hole injection layer and an electron injection layer and those three layers are held between a pair of electrodes. The organic EL devices have diode characteristics such that current flows more in one direction between the pair of electrodes than in the other direction. When a current flows from one of the electrodes toward the hole injection layer 31, the light emission layer 17, and the electron injection layer 32 into the other electrode, holes flowing into the light emission layer 17 from the hole injection layer 31 and electrons flowing into the light emission layer 17 from the electron injection layer 32 recombine to emit light. Even when a current flows in the opposite direction, holes and electrons flow into the light emission layer in small numbers, and thus no light is emitted. A current flowing in a direction that causes light emission is called a forward direction in some cases.

When a current for light emission, namely, a forward direction current flows, the electrode from which the current flows toward the organic layer is called an anode whereas the electrode into which the current flows from the organic layer is called a cathode. In the R subpixel of FIG. 2, the current flows from the lower electrode 12 toward the upper electrode 16, with the lower electrode 12 serving as the anode and the upper electrode 16 serving as the cathode. The same applies to the B subpixel. In the G subpixel, the current flows from the upper electrode 16 toward the lower electrode 13, with the lower electrode 13 serving as the cathode and the upper electrode 16 serving as the anode.

The lower electrodes 12, 13, and 19 which are provided in the R subpixel, the G subpixel, and the B subpixel, respectively, are separated from one another and driven independently by their respective drive circuits. Other drive circuits than the drive TFTs 30R, 30G, and 30B, which are illustrated in FIG. 2, include a storage capacitor and a switch for inputting data.

On the other hand, the upper electrode 16 is common to all pixels and subpixels. In the case where there is an electrode common to all pixels as this upper electrode 16, a light-emitting device having the common electrode as a cathode and a light-emitting device having the common electrode as an anode are indicated herein by a symbol (+) and a symbol (−), respectively. The plus and minus symbols attached to the subpixels of FIG. 1 represent the above.

The light-emitting apparatus of this embodiment arranges subpixels, as illustrated in FIG. 1, in which the layer structure of one subpixel is reverse to the layer structure of its adjacent subpixels. In other words, in the arrangement of FIG. 1 in which subpixels in each row are set in a repetitive sequence of R-G-B while subpixels adjacent to each other in the column direction share the same color, the connection of one subpixel is reverse to both the connection of a subpixel that is adjacent to the former in the row direction and the connection of a subpixel that is adjacent to the former in the column direction.

In the subpixel arrangement of FIG. 1, subpixels of three colors, R, G, and B constitute one pixel. The direction of a certain direction current of a subpixel of one color (for example, red) in a pixel is reverse to the direction of the certain direction current of a subpixel of the same color in its adjacent pixel.

When the same current flows in all subpixels to turn on the subpixels, an amount of current flowing into the common electrode and an amount of current flowing out of the common electrode are equal to each other and, overall, the current flow generated in the common electrode is not large. This makes the electric potential constant throughout the common electrode, thus preventing shading.

A subpixel of one color in a pixel has a connection with the common electrode that is reverse to that of a subpixel of the same color in its adjacent pixel. Even when a picture in which the dominant color is red is displayed with a lot of R light emission, the current direction in the common electrode is reversed between adjacent pixels, and shading is also prevented in this case.

In most natural images displayed, R color light, G color light, and B color light are emitted at various intensities and intermingle with one another. It is highly likely that, among subpixels turned on to display a natural image, the number of subpixels that have a (+) connection and the number of subpixels that have a (−) connection are substantially equal to each other. Accordingly, shading is little also in this case.

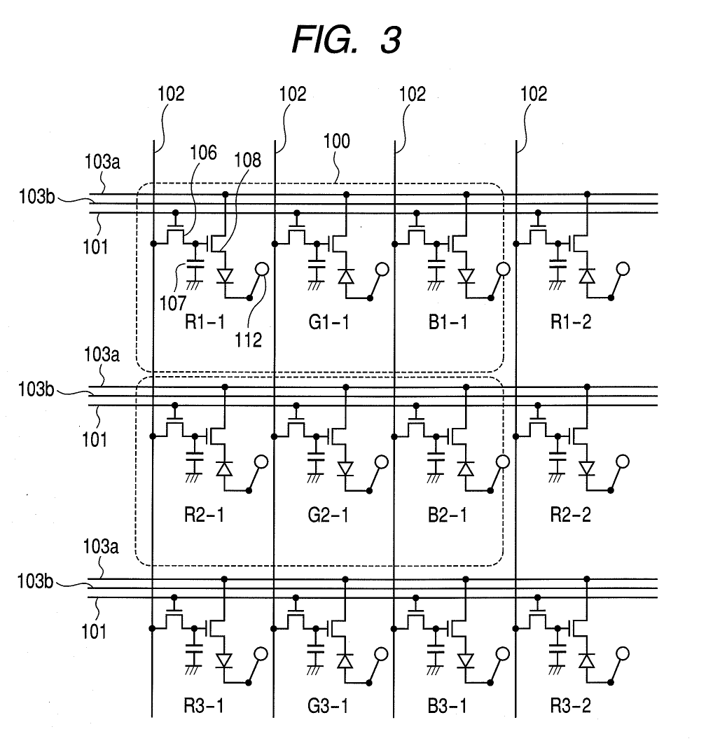

FIG. 3 is an equivalent circuit diagram of the light-emitting apparatus according to this embodiment.

In FIG. 3, denoted by 101 is a gate (scanning signal) wiring line; 102, a source (information signal) wiring line; 103, a current supply wiring line; 106, a voltage writing TFT; 107, a storage capacitor; 108, a current supplying TFT; and 112, a common electrode control wiring line. Each area enclosed by a broken line represents one pixel.

In each subpixel, the gate (scanning signal) wiring line 101 and the source (information signal) wiring line 102 are connected respectively to a gate electrode and a source electrode of the signal inputting TFT 106. The gate (scanning signal) wiring line 101 and the source (information signal) wiring line 102 receive voltages supplied from a scanning signal processing circuit (not shown) and an information signal processing circuit (not shown), respectively.

The signal inputting TFT 106 in each subpixel circuit has a drain electrode connected to the storage capacitor 107 and a gate electrode of the driver TFT 108.

The driver TFT 108 has a source electrode connected to the current supply wiring line (power supply line) 103 and a drain electrode connected to the lower electrode (anode or cathode) of a relevant organic light-emitting device. The upper electrode of the organic light-emitting device is connected to the common electrode which is kept at a constant electric potential (here, GND).

As illustrated in FIG. 3, the direction of connection with the common electrode (Vc) is reversed between the organic EL devices of adjacent subpixels. The drive current direction of a drive circuit connected to the electrode that is not the common electrode (Vc) is also reversed between adjacent subpixels. Accordingly, R1-1, B1-1, and other drive circuits that are connected to the anodes of organic EL devices are connected to a positive voltage source 103a, whereas G1-1 and other drive circuits that are connected to the cathodes of organic EL devices are connected to a negative voltage source 103b.

The light-emitting apparatus of this embodiment forms the organic layer by performing mask evaporation and patterning on the electron injection layer and the hole injection layer for each subpixel separately.

### Second Embodiment

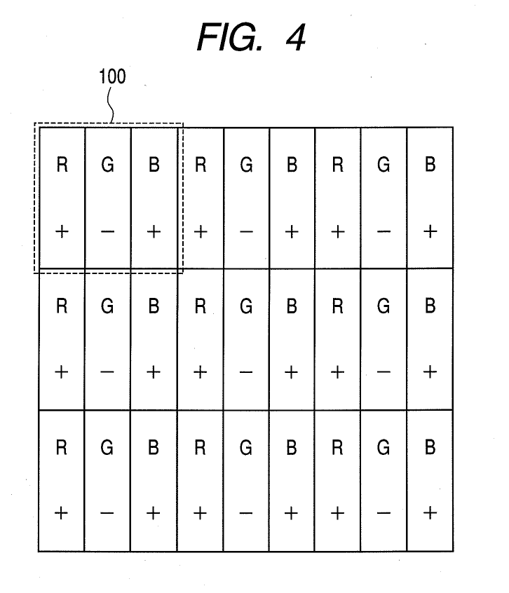

A pixel arrangement of FIG. 4 is a modification of the first embodiment in which the three subpixels R, G, and B of the pixel 100 have such layer structures that set the direction of a certain direction current ((+) connection or (−) connection) of one subpixel reverse to that of its adjacent subpixel, while the direction of the certain direction current ((+) connection or (−) connection) of a subpixel of one color in a pixel is identical to that of a subpixel of the same color in its adjacent pixel. In FIG. 4, the G light-emitting device alone is connected in the (−) direction whereas the R and B light-emitting devices are connected in the (+) direction.

This embodiment varies the direction in which an organic EL device is electrically connected to the common electrode (Vc) from one color to another. Organic EL devices separately applied with their color R, G, and B may thus exert the effects of the present invention without increasing organic EL film formation steps in number.

While the example of FIG. 4 sets the connection direction of the R light-emitting device and the B light-emitting device differently from the connection direction of the G light-emitting device, other combinations may be employed.

### Third Embodiment

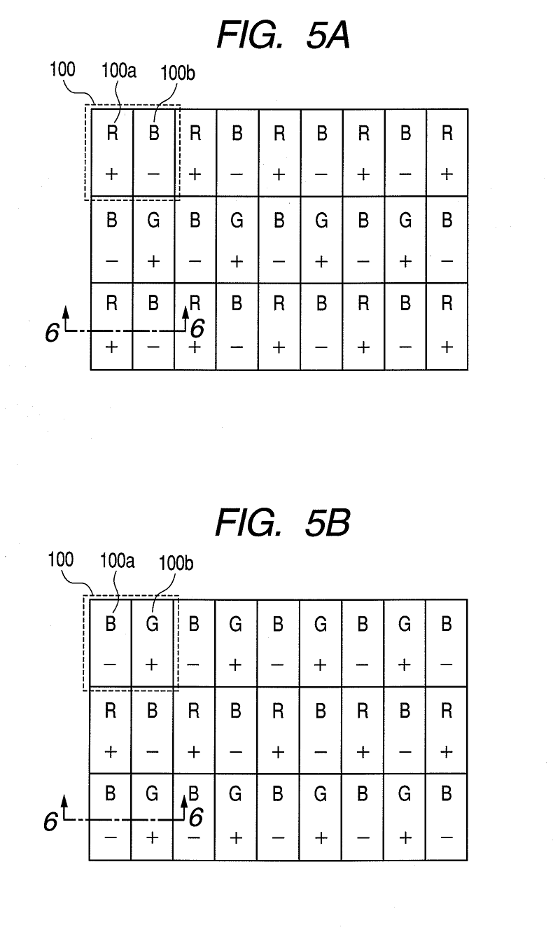

A subpixel arrangement according to a third embodiment of the present invention is illustrated in FIGS. 5A and 5B.

In this embodiment, the pixel 100 is formed of two subpixels 100a and 100b, which emit light of two different colors at different points in time. FIGS. 5A and 5B illustrate the colors of light that the subpixels 100a and 100b emit in two different subfields. Those two subfields are actually combined into one frame of image.

The subpixel 100a emit red (R) light and blue (B) light alternately. The subpixel 100b emit green (G) light and blue (B) light alternately. The subpixels 100a and 100b are arranged in a fixed pattern, and the pattern is cyclically repeated in the row direction and the column direction.

In the example of FIGS. 5A and 5B, the subpixel 100a and subpixel 100b of a single pixel take turns in emitting blue light. The pixels 100a and 100b do not emit red light and green light in combination, and do not emit blue light simultaneously.

Pixels adjacent to each other in the row direction have the same light emission sequence, whereas pixels adjacent to each other in the column direction have light emission sequences reverse to each other. Specifically, the subpixels 100a in the same row all emit red light in one period, and all emit blue light in the next period. The subpixels 100b in the same row all emit blue light in one period, and all emit green light in the next period. This phase is reversed in its adjacent row.

The order of light emission colors of the subpixels 100a and 100b and the correlation between adjacent pixels are related to a pixel layer structure described below.

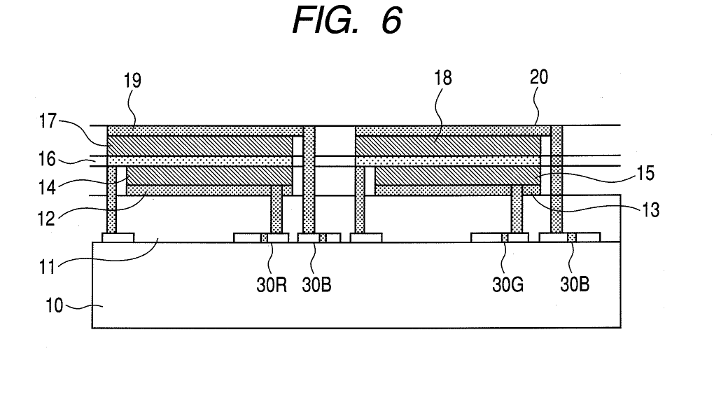

FIG. 6 is a cross-sectional view taken along line 6-6 of FIGS. 5A and 5B to illustrate the layer structure of the pixel 100 in a light-emitting apparatus of this embodiment.

Each subpixel includes three layers of electrodes and two layers of organic EL devices placed in gaps between the electrode layers. Denoted by 10 is a glass substrate; 11, a planarization layer; 14, an organic layer that contains a red (R) light emission layer; 15, an organic layer that contains a green (G) light emission layer; and 17 and 18, organic layers that contain blue (B) light emission layers. Denoted by 12 and 13 are lower electrodes; 16, a middle electrode; and 19 and 20, upper electrodes. The middle electrode 16 is a common electrode which is formed to be common to all pixels. The lower electrode and the upper electrode in one subpixel are separated from the lower electrode and the upper electrode in another subpixel, and are connected to the TFTs 30R, 30G, and 30B, which are drive circuits for R, G, and B, respectively, to be driven independently of other subpixels.

Each subpixel in this embodiment is structured such that two light-emitting devices are stacked. Two stacked light-emitting devices form a pair, and pairs of stacked light-emitting devices are arranged on the substrate.

The two subpixels in a pixel have different combinations of colors of stacked light-emitting devices, that is, one has a blue-red combination and the other has a green-blue combination.

Though omitted in FIG. 6, the organic layers 14, 15, 17, and 18 are all formed by stacking a hole injection layer, a light emission layer, and an electron injection layer in the stated order from the bottom upward. Each subpixel therefore emits light when a certain direction current flows from the lower electrode toward the upper electrode.

Of the three layers of electrodes, the middle electrode 16 located in the middle is the electrode that is common to all pixels. The subpixel-common electrode connection is (+) in the R light-emitting device and the G light-emitting device, and (−) in the B light-emitting device. The (+) and (−) symbols are indicated in the sub pixels of FIGS. 5A and 5B.

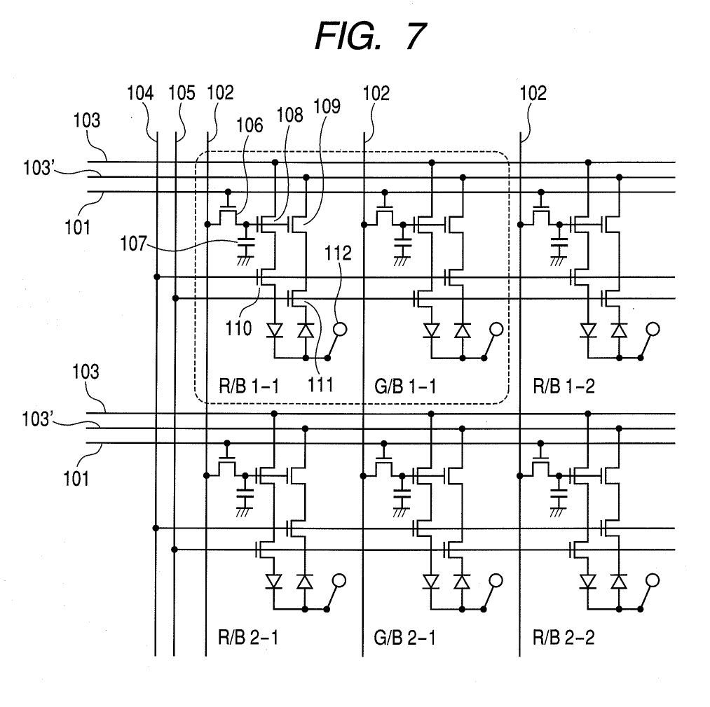

FIG. 7 is a diagram schematically illustrating a circuit of the light-emitting apparatus of FIG. 6.

An area enclosed by a dotted line of FIG. 7 represents one pixel 100, which contains the subpixel 100a and the subpixel 100b. The stacked light-emitting devices of FIG. 6 are illustrated in FIG. 7 as diodes that are connected to a common electrode 112, facing opposite directions. Connected to each diode are the switch 106, which inputs a signal from the data line 102, the storage capacitor 107, and a drive circuit formed of two TFTs. The switch 106 and the storage capacitor 107 are shared by the light-emitting devices in one sub-pixel.

The difference from the circuit of FIG. 3 is that two pixel selection wiring lines 104 and 105 and two pixel selecting TFTs 110 and 111 are provided.

In the subpixel 100a, the anode of the light-emitting device that contains an R light emission layer (lower electrode 12 of FIG. 6) is connected to a drain of the pixel selecting TFT 110, which is controlled through the pixel selection wiring line 104, and the cathode of the light-emitting device that contains a B light emission layer (upper electrode 19 of FIG. 6) is connected to a drain of the pixel selecting TFT 111, which is controlled through the pixel selection wiring line 105. This is reversed in the subpixel 100b, in which the anode of the light-emitting device that contains a G light emission layer (lower electrode 13 of FIG. 6) is connected to the drain of the pixel selecting TFT 111, which is controlled through the pixel selection wiring line 105, and the cathode of the light-emitting device that contains a B light emission layer (upper electrode 20 of FIG. 6) is connected to the drain of the pixel selecting TFT 110, which is controlled through the pixel selection wiring line 104.

The common electrode 16 is formed to be common to every pixel and every subpixel, and is connected to a metal wiring line formed on the substrate 10 through a contact hole opened in the outer peripheral region of the display region. The metal wiring line leads the common electrode 16 to a lead-out terminal to connect the common electrode 16 to an external power source Vcc.

Each information signal wiring line 102 receives subfield information signals which are sent from the information signal processing circuit after processed by time division processing. The information signals are then held in the storage capacitor 107 via the signal transmitting TFT 106.

The pixel selection wiring lines 104 and 105 enter into a selected state (reach the high level) alternately on a subfield basis. This causes one of the two stacked light-emitting devices to start emitting light for each subfield. Specifically, in a subfield period during which the pixel selection wiring line 104 is selected, the R light-emitting device of the subpixel 100a and the B light-emitting device of the subpixel 100b enter into a light emission state. In a subfield period during which the pixel selection wiring line 105 is selected, the B light-emitting device of the subpixel 100a and the G light-emitting device of the subpixel 100b enter into a light emission state.

Adjacent pixels in the row direction are built from identical circuits. The pixels therefore have the same light emission sequence and emit light of the same color.

Adjacent pixels in the column direction, on the other hand, are reversed in terms of connection between a pixel selection wiring line and a pixel selecting TFT as illustrated in FIG. 7, and therefore have light emission sequences of opposite phase. Specifically, in a subfield period during which the pixel selection wiring line 104 is selected, the B light-emitting device of the subpixel 100a and the G light-emitting device of the subpixel 100b enter into a light emission state. In a subfield period during which the pixel selection wiring line 105 is selected, the R light-emitting device of the subpixel 100a and the B light-emitting device of the subpixel 100b enter into a light emission state.

This is the mechanism of the light emission sequence described above with reference to FIGS. 5A and 5B.

The light emission sequence of FIGS. 5A and 5B is such that the (+) and (−) symbols attached to subpixels are reversed between adjacent subpixels in any subfield. As a result, shading is reduced in many images as in the first embodiment.

As has been described above, according to the present invention, the direction of a certain direction current flowing toward the common electrode (Vc) in one subpixel is electrically different from that in its adjacent subpixel. This means that only the differential amount of currents flowing in the organic EL devices of the subpixels is supplied through the common electrode (Vc) 112.

The great reduction in amount of current flowing in the common electrode (Vc) 112 significantly reduces shading caused by a voltage drop. In addition, the number of subpixels in which the direction of a current flowing toward the common electrode is (+) and the number of subpixels in which the direction of a current flowing toward the common electrode is (−) are substantially equal to each other in most images displayed, and hence the shading prevention effect is expected.

### (Production Method)

A production method for the light-emitting apparatus according to the third embodiment is described below.

First, TFTs 40 are formed on the glass substrate 10, and an insulating layer is formed to protect the TFTs.

Next, surface unevenness resulting from the above-mentioned TFT formation are planarized by forming the organic planarization layer 11.

Contact holes are formed in the insulating layer and the organic planarization layer 11 to establish electric contact with the drains 40 formed within the TFTs. Thereafter, the R pixel anode 12 and the G pixel anode 13 are formed on the organic planarization layer 11.

Those electrode patterns may be formed by any one of a wet process and a dry process, as long as the anode patterns formed are separated from one another.

UV/ozone cleaning is performed as pre-treatment, and then vacuum baking is performed to form the organic EL layers 14 and 15 on the substrate by evaporation.

To apply the R light emission layer and the G light emission layer separately, shadow masks specific to the respective arrangements of the R light emission layer and the G light emission layer may be used. Other methods including laser transfer may also be used without raising a problem.

Subsequently, an electron transportation layer and an electron injection layer are formed. A transparent electrode or a semi-transmissive film is then formed as the common electrode 16 (which doubles as the cathode of the lower organic EL layer and as the anode of the upper organic EL layer).

The second organic layer (containing the B light emission layer) is formed on the cathode electrode 16.

The B light emission layer is formed after a hole transportation layer is formed. An electron transportation layer and an electron injection layer are then formed.

Lastly, the upper electrodes 19 and 20 are formed and patterned. Through the above-mentioned steps, stacked organic EL devices which exhibit diode characteristics are formed within the same sub-pixel.

### Fourth Embodiment

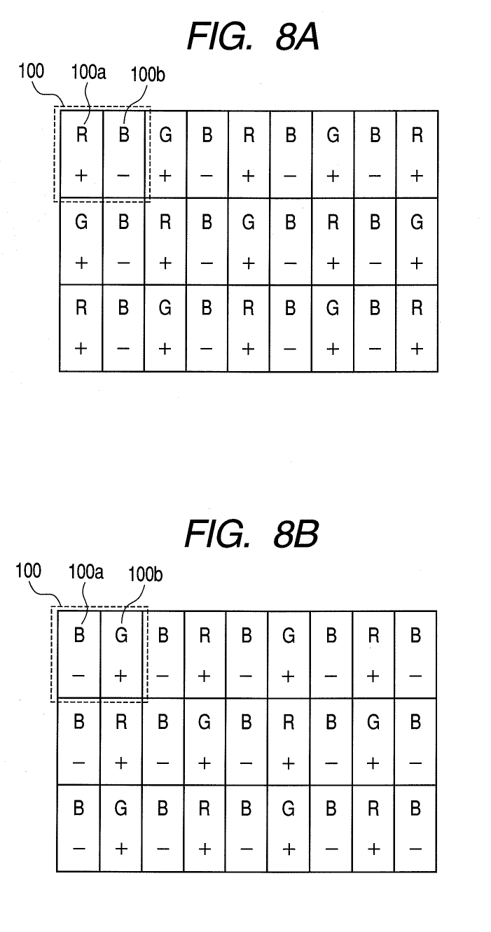

In the third embodiment, B light-emitting devices provided as the second organic EL layer are arranged in a dot pattern instead of allowing side-by-side emission of blue light in each subfield. Alternatively, consecutive pixels in the column direction may emit blue light, thereby giving a linear pattern to blue light emission as illustrated in FIGS. 8A and 8B. This B light emission aligned in the column direction may be accomplished by arranging pixels so that the arrangement of a pair of a red light-emitting device and a blue light-emitting device and a pair of a green light-emitting device and a blue light-emitting device is reversed from row to row.

The amount of current flowing in the common electrode may be reduced in this structure, too. In this case, however, the organic light-emitting devices in sub-pixels that are disposed along the same signal line have the same diode connection direction, and the load on the current supply lines is accordingly heavier.

The organic emission layer of the second organic EL layer in this embodiment emits light in a vertical linear pattern in each subfield. Alternatively, the organic emission layer may emit light in a horizontal linear pattern.

While the organic emission layer of the second organic EL layer emits blue light in this embodiment, the second organic EL layer may be the R light-emitting device or the G light-emitting device.

Each first organic EL layer in this embodiment is connected with the common electrode (Vc) in electrically the same direction, and the same applies to the second organic EL layer. Alternatively, the direction of connection with the common electrode (Vc) may be varied from one first organic EL layer to another, or from one second organic EL layer to another.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-171749, filed Jun. 30, 2008 which is hereby incorporated by reference herein in its entirety.

1. A light-emitting apparatus comprising a plurality of light-emitting devices arranged on a substrate, the plurality of light-emitting devices each comprising a pair of electrodes and an organic emission layer which is interposed between the pair of electrodes with one of the pair of electrodes serving as an anode and the other of the pair of electrodes serving as a cathode,
wherein one of the pair of electrodes is an electrode common to the plurality of light-emitting devices, and
wherein, of the plurality of light-emitting devices, ones that have the common electrode as their anodes and ones that have the common electrode as their cathodes are arranged alternately.

2. The light-emitting apparatus according to claim 1, wherein one of the pair of electrodes is an electrode that is provided on the organic layer and common to the plurality of light-emitting devices, whereas the other of the pair of electrodes is a separate electrode provided for each of the plurality of light-emitting devices, and wherein a current for light emission that flows in one of the plurality of light-emitting devices and a current for light emission that flows in its adjacent light-emitting device are in opposite directions.

3. The light-emitting apparatus according to claim 1, wherein three of the plurality of light-emitting devices that respectively emit red light, green light, and blue light are grouped together to constitute a pixel, and wherein directions of currents for light emission that flow in the light-emitting devices of one pixel are reverse to directions of currents for light emission that flow in the light-emitting devices of its adjacent pixel.

4. The light-emitting apparatus according to claim 1, wherein three of the plurality of light-emitting devices that respectively emit red light, green light, and blue light are grouped together to constitute a pixel, and wherein directions of currents for light emission that flow in the light-emitting devices of one pixel are the same as directions of currents for light emission that flow in the light-emitting devices of its adjacent pixel, and one of the directions of the currents for light emission is opposite to the other two directions of the currents for light emission in a pixel.

5. The light-emitting apparatus according to claim 1, wherein, of the pair of electrodes, a separate electrode provided for each light-emitting device, is connected to a drive circuit, and the drive circuit is connected to one of a plurality of different voltage sources that is determined depending on a direction of a current for light emission.

6. A light-emitting apparatus comprising multiple pairs of stacked light-emitting devices arranged on a substrate, the pair of stacked light-emitting devices each comprising two layers of organic emission layers and three layers of electrodes, the organic emission layers each being held in a gap between two of the three layers of electrodes,
wherein, of the three layers of electrodes, a middle electrode serves as an anode of one of the pair of stacked light-emitting devices and also as a cathode of the other of the pair of stacked light-emitting devices, and is common to the multiple pairs of light-emitting devices arranged on the substrate,
wherein the pair of stacked light-emitting devices emit light during different periods from each other, and
wherein, of the pair of stacked light-emitting devices, one whose anode is the common electrode emits light during the same period as one of their adjacent pair of stacked light-emitting devices whose cathode is the common electrode.

7. The light-emitting apparatus according to claim 6, wherein a current for light emission in the pair of stacked light-emitting devices has the same direction as a stacking direction.

8. The light-emitting apparatus according to claim 7, wherein, of the multiple pairs of stacked light-emitting devices arranged on the substrate, the direction of the current for light emission in one pair is the same as the direction of the current for light emission in another pair.

9. The light-emitting apparatus according to claim 6, wherein the multiple pairs of stacked light-emitting devices comprise a pair of a red light-emitting device and a blue light-emitting device that are stacked in the stated order and a pair of a green light-emitting device and a blue light-emitting device that are stacked in the stated order are placed next to each other in a row direction to constitute a pixel, and wherein the multiple pairs of stacked light-emitting devices are arranged as the pixels.

10. The light-emitting apparatus according to claim 9, wherein the pixels are arranged such that arrangement of the pair of the red light-emitting device and the blue light-emitting device and the pair of the green light-emitting device and the blue light-emitting device is reversed from row to row.

11. The light-emitting apparatus according to claims 6, wherein, of the three layers of electrodes, two electrodes are each formed separately for each light-emitting device, and a drive circuit is connected to each of the two separate electrodes, and wherein the drive circuit is connected to one of a plurality of different voltage sources that is determined depending on a direction of a current for light emission.
